(19) United States
(12) Patent Application Publication
(10) Pub. No.: US 2006/0289895 A1
(43) Pub. Date: Dec. 28, 2006

(54) Semiconductor device

(75) Inventor: Yoshiki Kamata, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 11/472,450

(22) Filed: Jun. 22, 2006

(30) Foreign Application Priority Data
Jun. 23, 2005 (JP) P2005-183234

(51) Int. Cl. H01L 31/00

(52) U.S. Cl. 257/192

(57) ABSTRACT

A semiconductor device includes a channel region, an oxide film, a gate electrode and source/drain regions. The channel region includes Ge. The oxide film is formed on the channel region. The oxide film includes Si and a metallic element M selected from the group consisting of Zr, Hf, La, Ce, Pr, Nd, Pm, Sm, Eu, Gd, Tb, Dy, Ho, Er, Tm, Yb and Lu. The gate electrode is formed on the oxide film. The source/drain regions are disposed across the channel region from each other in a longitudinal direction of the channel region.

### CROSS-REFERENCE TO RELATED APPLICATIONS

This application is based upon and claims the benefit of priority from the Japanese Patent Application No. 2005-183234 filed on Jun. 23, 2005; the entire contents of which are incorporated herein by reference.

### BACKGROUND OF THE INVENTION

1. Field of the Invention

The invention relates to a semiconductor device including a field effect transistor.

2. Description of the Related Art

While a silicon single crystal substrate has been used as a substrate for a semiconductor device, a germanium substrate is receiving attention owing to the large mobility of electrons and holes thereof.

In order to decrease an effective oxide thickness (EOT), a deposited film containing a highly dielectric material is being used as a gate insulating film of a transistor in place of a conventional thermally oxidized film.

Various measures are being studied and proposed for forming a highly dielectric film on a germanium substrate in recent years (as described, for example, in “A Germanium NMOSFET Process Integrating Metal Gate and Improved Hi□k Dielectrics” (C. O. Chui, IDEM (2003), p. 437).

However, some reports note that a large hysteresis is obtained upon capacity measurement of a MOS capacitor with a high-k/Ge gate stack structure (as described, for example, in “Local epitaxial growth of ZrO2 on Ge (100) substrates by atomic layer epitaxy” (H. Kim, Applied Physics Letters, Sep. 29, 2003, vol. 83, p. 2647). The large hysteresis causes threshold shift and threshold fluctuation upon operation of the transistor.

### SUMMARY OF THE INVENTION

The invention provides a semiconductor device having a small hysteresis.

According to an aspect of the invention, a semiconductor device includes a channel region, an oxide film, a gate electrode and source/drain regions. The channel region includes Ge. The oxide film is formed on the channel region. The oxide film includes Si and a metallic element M selected from the group consisting of Zr, Hf, La, Ce, Pr, Nd, Pm, Sm, Eu, Gd, Tb, Dy, Ho, Er, Tm, Yb and Lu. The gate electrode is formed on the oxide film. The source/drain regions are disposed across the channel region from each other in a longitudinal direction of the channel region.

According to another aspect of the invention, a semiconductor device includes a channel region, an oxide film, a gate electrode and source/drain regions. The channel region includes Ge. The oxide film is formed on the channel region. The oxide film includes a metallic element M selected from the group consisting of Zr, Hf, La, Ce, Pr, Nd, Pm, Sm, Eu, Gd, Tb, Dy, Ho, Er, Tm, Yb and Lu. The oxide film is in an amorphous state. The gate electrode is formed on the oxide film. The source/drain regions are disposed across the channel region from each other in a longitudinal direction of the channel region.

According to further another aspect of the invention, a semiconductor device includes a substrate, a channel region in the substrate, source/drain regions in the substrate, an insulting film and a gate electrode. The channel region contains Ge. The source/drain regions are disposed across the channel region from each other in a longitudinal direction of the channel region. The insulating film is formed on the channel region. The insulating film contains an oxide of Si and a metallic element M selected from the group consisting of Zr, Hf, La, Ce, Pr, Nd, Pm, Sm, Eu, Gd, Tb, Dy, Ho, Er, Tm, Yb and Lu. The gate electrode is formed on the insulating film.

According to still another aspect of the invention, a semiconductor device includes a substrate, a channel region in the substrate, source/drain regions in the substrate, an insulating film and a gate electrode. The channel region contains Ge. The source/drain regions are disposed across the channel region from each other in a longitudinal direction of the channel region. The insulating film is formed on the channel region. The insulating film contains an oxide of a metallic element M selected from the group consisting of Zr, Hf, La, Ce, Pr, Nd, Pm, Sm, Eu, Gd, Tb, Dy, Ho, Er, Tm, Yb and Lu. The insulating film is in an amorphous state. The gate electrode is formed on the insulating film.

According to the above structure, a semiconductor device having a small hysteresis can be provided.

### BRIEF DESCRIPTION OF THE DRAWINGS

FIGS. 1A and 1B are graphs showing hysteresis of ZrO₂/Ge and ZrSiO/Ge gate stack structures.

FIGS. 2A and 2B are graphs showing effective hole mobility of ZrO₂/Ge and ZrSiO/Ge gate stack structures.

FIGS. 3A and 3B are graphs showing in-plane XRD results of ZrO₂/Ge and ZrSiO/Ge gate stack structures.

FIG. 4 is a graph showing effective hole mobility of a ZrON/Ge structure.

FIGS. 5A and B are graphs showing effective hole mobility of a surface orientation of a Ge substrate (100), (111) and (110).

FIG. 6 is a schematic cross sectional view of a CMOSFET according to an embodiment of the invention in a longitudinal direction of a gate.

### DETAILED DESCRIPTION OF EXEMPLARY EMBODIMENTS

Exemplary embodiments of the invention will be described below with reference to the drawings. In the exemplary embodiments, the same reference signs are assigned to the same elements for omitting duplicate descriptions. The drawings are schematic illustrations for promoting explanation and understanding, and the shapes, dimensions, ratios and the like therein may vary in practical devices, in which appropriate changes in design may be made in consideration of the following descriptions and the known technologies.

In the following exemplary embodiments, a CMOSFET (complementary metal-oxide-semiconductor field effect transistor) will be described, but the exemplary embodiments may be applied to a single MOSFET.

The exemplary embodiments may also be applied to PROM (programmable read only memory), such as EPROM (erasable programmable read only memory), EEPROM (electrically EPROM) and flash memory.

Furthermore, the invention encompasses a memory, a logic circuit and the like having the aforementioned semiconductor devices integrated therein, and a system LSI having them on one chip.

An example of a CMOSFET according to an exemplary embodiment will be described with reference to FIG. 6.

FIG. 6 is a schematic cross sectional view of a CMOSFET according to the exemplary embodiment taken along the longitudinal direction of a gate.

As shown in FIG. 6, a p-type semiconductor layer 2 and an n-type semiconductor layer 3 are formed on a semiconductor substrate 1. An n-MOSFET is formed in the p-type semiconductor layer 2, a p-MOSFET is formed in the n-type semiconductor layer 3, and device isolation 4 is formed therebetween. The n-MOSFET and the p-MOSFET function complementarily with each other to constitute a CMOSFET.

The n-MOSFET will be described. A gate insulating film 5 having a first or second highly dielectric film described later is formed on the upper surface of the p-type semiconductor layer 2. A gate electrode 6 is formed on the gate insulating film 5. Gate sidewalls 15 are formed across the gate insulating film 5 and the gate electrode 6 from each other in the longitudinal direction of the gate. A channel region, which contains Ge of the upper surface of the p-type semiconductor layer 2 as a major component, is formed immediately under the gate insulating film 5. First source-drain regions 9 are formed on the surface of the p-type semiconductor layer 2 to sandwich the channel region therebetween in the longitudinal direction of the gate. Each first source-drain regions 9 includes an extension region and a diffusion layer. The extension regions sandwich the channel region therebetween in the longitudinal direction of the gate. The diffusion layers sandwich the extension regions therebetween in the longitudinal direction of the gate. The diffusion layers are formed to have a larger depth than the extension region. Contact electrodes 10 are formed on the first source-drain regions 9.

In the p-MOSFET, an n-type semiconductor layer 3, a gate insulating film 5, a gate electrode 8, gate sidewalls 15, second source-drain regions 11 and a contact electrode 10 are formed in the similar manner as in the n-MOSFET.

The first highly dielectric film is a film containing an oxide containing Si and a metallic element M selected from the group consisting of Zr, Hf and La elements. Examples of the first highly dielectric film include ZrSiO, HfSiO, LaSiO, ZrSiON, HfSiON, LaSiON, ZrAlSiO, HfAlSiO, LaAlSiO, ZrAlSiON, HfAlSiON and LaAlSiON.

The second highly dielectric film is an amorphous film containing an oxide containing a metallic element M selected from the group consisting of Zr, Hf and La elements. Examples of the second highly dielectric film include ZrON, HfON, LaON, ZrSiO, HfSiO, LaSiO, ZrSiON, HfSiON, LaSiON, ZrAlSiO, HfAlSiO, LaAlSiO, ZrAlSiON, HfAlSiON and LaAlSiON.

The La element herein is one of La, Ce, Pr, Nd, Pm, Sm, Eu, Gd, Tb, Dy, Ho, Er, Tm, Yb and Lu, and La is particularly preferred among these.

The gate insulating film 5 is not particularly limited in thickness, and may be one mono-layer or more. In order to prevent the gate capacity from being reduced, it is necessary to make the gate insulating film 5 as thin as possible. Specifically, it is preferably that the gate insulating film 5 has 2 nm or less in terms of SiO₂.

The semiconductor substrate 1 may be formed of Si, SiGe, Ge or strain Si.

The p-type semiconductor layer 2 and the n-type semiconductor layer 3 may be those having a channel region containing Ge as a major component. Specifically, the Ge concentration is in a range of 50% to 100%. In the case where the Ge concentration is 50% or more, the activation temperature of the dopant can be effectively lowered. In order to improve the effective mobility of electrons and holes, the Ge concentration is preferably 80% or more, and more preferably 100%. The Ge concentration herein is a concentration with respect to the total amount of the semiconductor elements except for the impurity concentration. Si and Ge have solid solubility in each other over the entire ratio, i.e., can be mixed with each other in an arbitrary concentration. Particularly, when x of Si_{c}Ge₁₋ₓ is equal to or less than about 0.85, a band edge of a conductive material of SiₓGe₁₋ₓ is determined based on A point attributed to the band structure of Si. On the other hand, when x is larger than about 0.85, the band edge of the conductive material of SiₓGe₁₋ₓ is determined based on L point attributed to the band structure of Ge. Therefore, in order to enjoy high mobility of Ge in an n-MOSFET, it is preferable that Ge concentration is larger than 85%. Furthermore, the p-type semiconductor substrate 2 and the n-type semiconductor substrate 3 may be different from each other in Ge concentration. An upper limit of solid solubility of Ge in p-type impurities is higher than that of Si, while an upper limit of solid solubility of Ge in n-type impurities is lower than that of Si. Therefore, Ge concentration of the n-type semiconductor substrate 3 for the p-MOSFET is higher than that of the p-semiconductor substrate 2 for the n-MOSFET, activation of impurities are improved effectively. In an extreme example, the p-MOSFET may have 100% Ge channel, and the n-MOSFET may have 100% Si channel.

The channel regions of the p-type semiconductor layer 2 and the n-type semiconductor layer 3 preferably have a surface orientation (100).

The gate electrodes 6 and 8 are formed of polycrystalline silicon (poly-Si), a semiconductor compound such as SiGe, a metal having heat resistance to a temperature of from 400 to 600° C., or a metallic compound having heat resistance to a temperature of from 400 to 600° C.

The source-drain regions 9 and 11 may be such a structure that is necessary for transistors of each generation, such as a combination of a shallow junction and a deep junction as a high-concentration impurity diffusion layer, or a silicide layer. In the following embodiments, the structures may be replaced by any other necessary structures unless otherwise indicated.

Examples of the contact electrode 10 include NiSiₓ, various silicides showing metallic electroconductivity such as silicides of V, Cr, Mn, Y, Mo, Ru, Rh, Hf, Ta, W, Ir, Co, Ti, Er, Pd, Zr, Gd, Dy, Ho and Er, and metallic germanide (MGeₓ) where a part of Si thereof is replaced with Ge.

The device isolations 4 and the gate sidewalls 15 may be formed of an insulating material. For example, a shallow trench isolation (STI) may be used as the device isolations 4. The STI formed by the following method. A surface of a Ge substrate in which a natural oxide film or a chemical oxide film is formed is nitrided to form Ge oxide and nitride film. Thereafter, a general insulating material such as Zr silicate, GeON or SiO₂ is embedded in a region in question and planarization processing such as CMP is performed. Also, the Ge oxide and nitride film at Ge interface of the STI is not necessarily formed. The device isolation 4 and the gate sidewalls 15 may be replaced by void, if possible.

According to the exemplary embodiment, the hysteresis of the semiconductor device can be decreased as described in the example later.

According to the exemplary embodiment, the channel mobility of the semiconductor device can be decreased as described in the example later.

The first highly dielectric film preferably contains the metallic element M and Si in a ratio M/(M+Si) of from 10 to 90%.

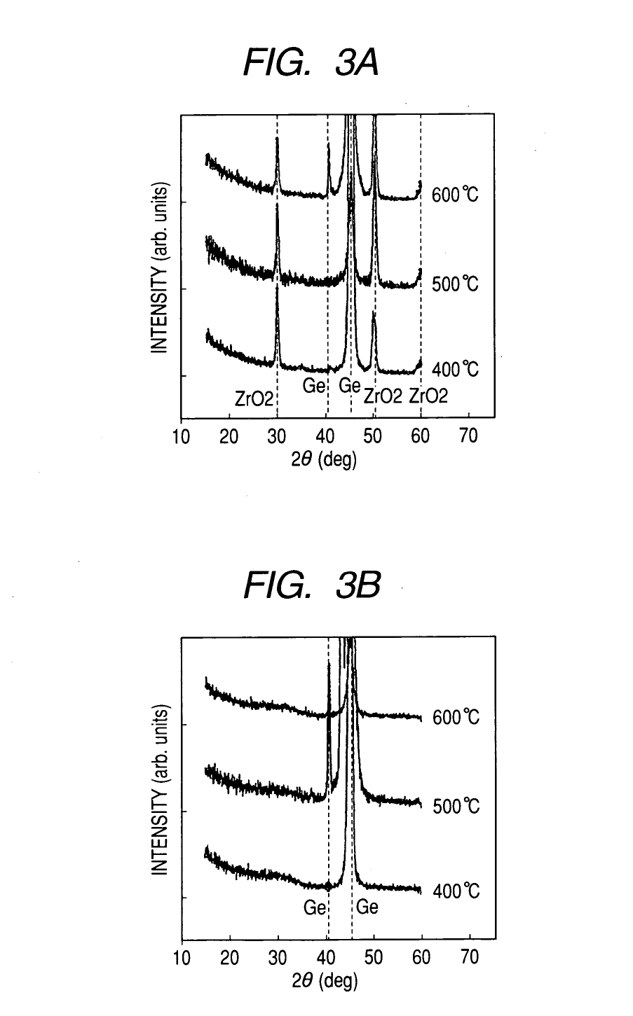

In the case where the ratio M/(M+Si) is 10% or more, the specific dielectric constant may be 8 or more, and therefore the physical thickness can be 2 nm or more for attaining 1 nm of the gate insulating film in terms of SiO₂, whereby the gate leakage electric current can be considerably reduced. In the case where the ratio M/(M+Si) is 90% or less, such a function is maintained that the amorphous state is maintained up to about 600° C. as shown in FIG. 3B.

The ratio M/(M+Si) is preferably 25% or more providing a specific dielectric constant of about 12, and more preferably 40% or more providing a specific dielectric constant of about 16. According to the increase in specific dielectric constant, the physical thickness can be further increased with respect to the same thickness in terms of SiO₂, whereby the gate leakage electric current can be further reduced. With respect to the upper limit of the ratio M/(M+Si), a higher specific dielectric constant is obtained with a higher ratio M/(M+Si), but the band offset of Ge and the highly dielectric film is decreased as the counter action thereof to exhibit such a phenomenon that the leakage electric current is increased. Therefore, it is most preferred that the ratio M/(M+Si) is 70% or less for preventing the band offset from being decreased.

The gate insulating film is preferably a highly dielectric film corresponding to both the first highly dielectric film and the second highly dielectric film. In other words, the gate insulating film is preferably an amorphous film containing an oxide containing a metallic element M selected from the group consisting of Zr, Hf and La elements, and Si. This is because the oxide has a specific dielectric constant higher than SiO₂, and thereby the thickness in terms of SiO₂ can be decreased to 1 nm or less. Furthermore, an amorphous oxide has high resistance against diffusion of impurities from the gate electrode and the substrate, and can avoid such problems as fluctuation in device characteristics, such as threshold voltage, caused by spatial fluctuation in characteristics specifically occurring in crystalline oxides.

The metallic element M is preferably Zr. This is because an oxide containing Zr has a high specific dielectric constant of about from 12 to 30 and a band gap of 5 eV or more, whereby the thickness in terms of SiO₂ can be decreased with the gate leakage electric current being suppressed to a low level. An oxide containing Zr and Si maintains an amorphous state at a temperature of about 600° C., whereby the aforementioned advantages peculiar to an amorphous oxide.

The metallic element M is also preferably Hf. This is because an oxide containing Hf has a high specific dielectric constant of about from 12 to 30 and a band gap of 5 eV or more, whereby the thickness in terms of SiO₂ can be decreased with the gate leakage electric current being suppressed to a low level. An oxide containing Hf and Si maintains an amorphous state at a temperature of about 700° C., whereby the aforementioned advantages peculiar to an amorphous oxide.

In the case where the highly dielectric film contains N, the N concentration is preferably from 5 to 30% by atom, and more preferably from 10 to 20% by atom. In the case where the N concentration is 5% by atom or more, it is possible in principle to maintain an amorphous state of the oxide in a high temperature process, and more preferably the amorphous state can be substantially completely maintained with an N concentration of 10% by atom or more. The function of maintaining an amorphous state is conspicuous with a higher N concentration, and the N concentration is preferably as high as possible particularly in consideration of a high temperature environment. However, the band gap of the oxide is decreased to deteriorate the insulating property of the film with a too higher N concentration. The tendency becomes notable typically with an N concentration of 30% by atom or more, and therefore, the N concentration is preferably 30% by atom or less, and more preferably 20% by atom or less from the standpoint of maintaining the band gap to the level without addition of nitrogen.

In the case where the highly dielectric film contains N, the concentration peak of nitrogen in the thickness direction of the gate insulating film is preferably above the center in the thickness direction of the gate insulating film, i.e., on the side of the gate electrode.

In the case where the highly dielectric film contains Ge, the Ge concentration is preferably from 0.5 to 26% by atom, and more preferably from 1 to 3% by atom. This is because when 0.5% by atom or more of Ge is contained in the highly dielectric film, the interface characteristics where the compositional discontinuity at the interface to Ge is relaxed is stabilized, and more preferably 1% by atom or more of Ge is contained. The highly dielectric film containing 26% by atom or more of Ge is considerably deteriorated in specific dielectric constant, and thus the Ge concentration is preferably 26% by atom or less. The Ge concentration is more preferably 3% by atom or less for preventing the specific dielectric constant from being largely deteriorated in comparison to the case without addition of Ge.

An interface transition layer (interface layer) may be provided between the Ge substrate and the highly dielectric layer. The interface layer may be constituted by the constitutional elements of the Ge substrate and the constitutional elements of the highly dielectric layer. The interface layer has such a function that the different substances, i.e., Ge and the highly dielectric layer, are joined reasonably, whereby structural defects, such as interface levels and fixed charges, can be decreased to improve the device characteristics considerably.

Examples of the interface layer for a silicate (MSiₓO_{y}) and the Ge substrate include MGeₓO_{y}, SiGeₓO_{y}, MSiₓO_{y}, SiOₓ, GeOₓ, MOₓ and MSiₓGe_{y}O_{z}. Examples of the interface layer for a metallic oxinitride (MON) and the Ge substrate include MᵥSi_{w}GeₓO_{y}N_{z} (where v+w+x+y+Z=1, and 1≧v, w, x, y and z≧0).

### EXAMPLES

The inventor actually fabricated and evaluated a device having a gate stack structure with a highly dielectric film and a Ge substrate. Specifically, the inventor fabricated gate stack structures having ZrO₂/Ge and ZrSiO/Ge as a highly dielectric film/Ge substrate. The Ge substrate had a surface orientation (100). The highly dielectric film had a thickness of 3 nm. The ratio Zr/(Zr+Si) was 50%. The gate stack structure having ZrSiO as a highly dielectric film/Ge substrate thus fabricated was subjected to a nitrogen heat treatment at 500° C. for 30 minutes.

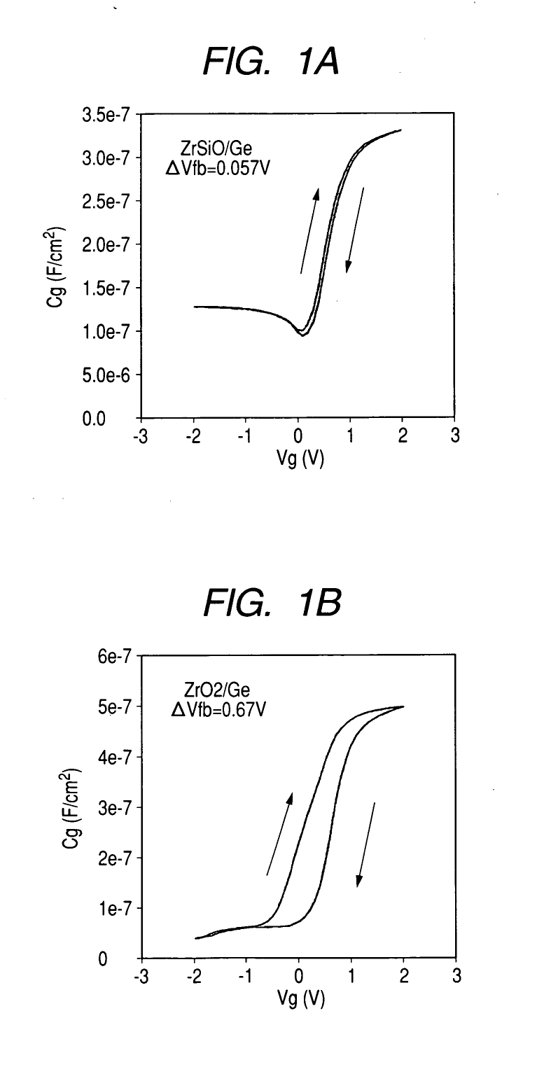

The inventor measured capacity of the ZrO₂/Ge gate stack structure and that of ZrSiO/Ge gate stack structures. The results are shown in FIGS. 1A and 1B. In FIGS. 1A and 1B, the hysteresis is defined as ΔVfb with the flat band used as a reference capacity value.

As shown in FIGS. 1A and 1B, the ZrO₂/Ge structure had ΔVfb of 0.67 V, and the ZrSiO/Ge structure had ΔVfb of 0.057 V.

Accordingly, it is understood that the ZrSiO/Ge structure is improved in ΔVfb by one digit or more. A small hysteresis value decreases the fluctuation in threshold value. Decrease of the fluctuation in threshold value decreases the electric power voltage to provide a device with low electric power consumption. In general, in order to avoid malfunction of circuits, it is necessary to set the electric power voltage to a value that is about 25 times the fluctuation in threshold value. In consideration of commercial production, a fluctuation in threshold value of several tens mV or less is required. The ΔVfb value of the ZrSiO/Ge structure of the example satisfied the requirement.

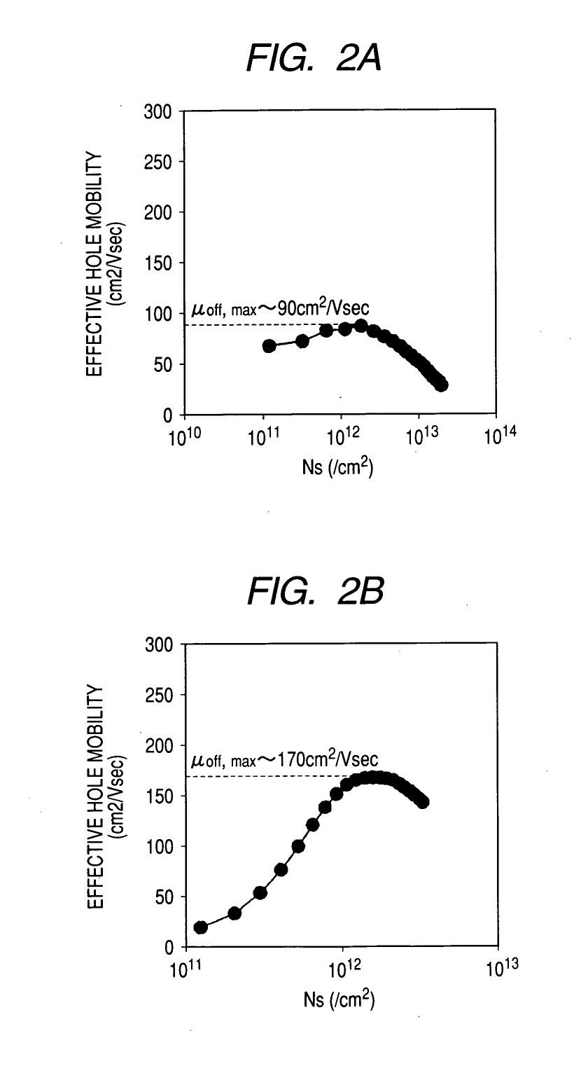

The inventor measured effective hole mobility μ_{eff} of the ZrO₂/Ge gate stack structure and that of ZrSiO/Ge gate stack structure. The results are shown in FIGS. 2A and 2B.

As shown in FIGS. 2A and 2B, the ZrO₂/Ge structure had a maximum value of μ_{eff} of 90 cm²/Vsec as an index of the device performance. The ZrSiO/Ge structure had a maximum value of μ_{eff} of 170 cm²/Vsec. In FIGS. 2A and 2B, Ns represents the surface charge density.

As a factor of the small hysteresis and the large mobility of the ZrSiO/Ge structure as compared to the ZrO₂/Ge structure, differences in crystallinity of the films and the interface characteristics are considered.

The crystallinity of the films of the ZrO₂/Ge structure and ZrSiO/Ge structure will be described with reference to FIGS. 3A and 3B. FIGS. 3A and 3B are graphs showing in-plane XRD results after a nitrogen heat treatment at 400, 500 and 600° C.

As shown in FIG. 3A, it is understood that in the ZrO₂/Ge stack structure, the ZrO₂ film was crystallized after the nitrogen heat treatment at 400° C. It was confirmed that the ZrO₂ film was in an amorphous state after deposition. Therefore, it is considered that the ZrO₂ film was crystallized due to the heat treatment.

The results shown in FIG. 3A will be described in more detail. The film was identified as ZrO₂ from comparison of FIG. 3A with the crystal system database of JCPDS. The peaks at 2θ=30.110°, 50.219° and 59.738° corresponded to (111), (220) and (311) of cubic ZrO₂, respectively. The peak at 2θ=45.305° corresponded to Ge (220) upon using CuKα as a radiation source. Due to sensitivity priority measurement, FIG. 3A included peaks of Ge (220) with other radiation sources, and the peaks at 40.7° and 43.3° corresponded to CuKβ and WLα, respectively.

In the ZrSiO/Ge stack structure, the film was not crystallized due to the nitrogen heat treatment at 600° C. or less and maintained an amorphous state as shown in FIG. 3B.

A silicate on a Si substrate has been investigated for crystallinity in a high temperature range of about 1,000° C. This is because the activation temperature of a dopant in a Si substrate is about 1,000° C. In a Ge substrate, on the other hand, a dopant can be activated at a temperature of about 400° C. owing to the low melting point of 938° C. Therefore, a temperature of from 400 to 600° C. is considered as a practical process temperature for forming a device.

The electric characteristics, such as hysteresis and mobility, of these structures are ascribable to the difference in crystallinity thereof. In general, a film forms polycrystals rather than single crystal upon crystallization, and thus has crystal grain boundaries. There is such a tendency that impurities are distributed at crystal grain boundaries. Accordingly, in the case where there are crystal grain boundaries in the channel region of a transistor where carriers pass through, it is expected that potential fluctuation of the channel part is increased, and as a result, the mobility in the ZrO₂/Ge structure is deteriorated. It is also considered that the large hysteresis of the ZrO₂/Ge structure is ascribable to the crystal grain boundaries.

In the ZrSiO/Ge structure, on the other hand, it is considered that the electric characteristics are improved as compared to the ZrO₂/Ge structure because the film is in an amorphous state.

It is understood from the above that such a treatment is preferably effected that improves the crystallization heat resistance of the film. Specifically, it is preferred to use a highly dielectric film containing nitrogen. Furthermore, it is found from the experimental results that in the case where gate insulating film contains nitrogen, it is preferred that the concentration peak of nitrogen in the thickness direction of the gate insulating film is above the center in the thickness direction of the gate insulating film, i.e., on the side of the gate electrode.

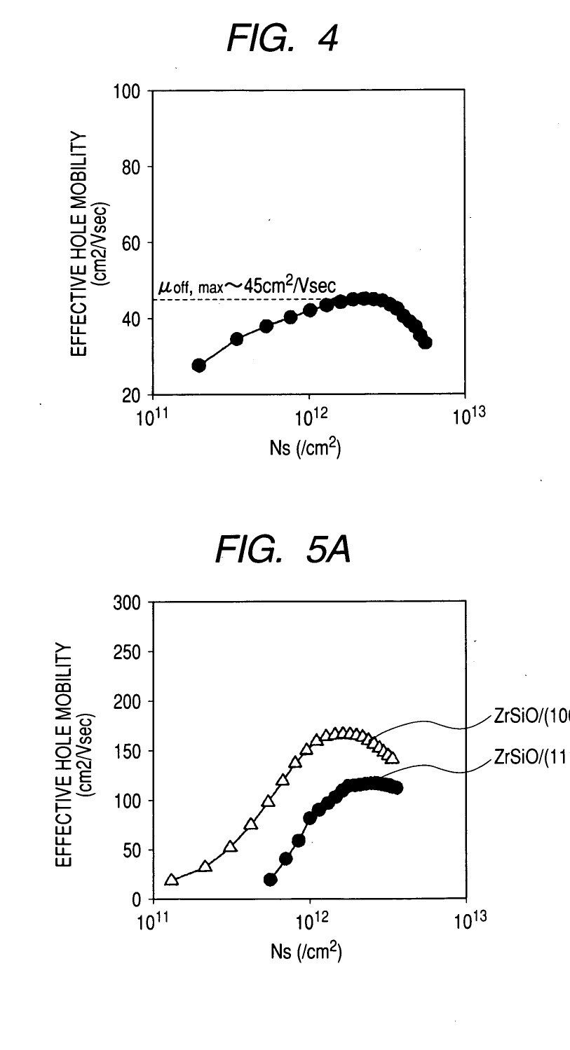

FIG. 4 is a graph showing hole mobility of a ZrON/Ge structure using ZrON having a nitrogen concentration uniform in the thickness direction of the film applied as a gate insulating film to a Ge substrate. In FIG. 4, Ns represents the surface charge density. As compared to the maximum value of hole mobility of 90 cm²/Vsec of the ZrO₂/Ge structure shown in FIG. 2A, it is found that the hole mobility of the ZrON/Ge structure is largely deteriorated to 45 cm²/Vsec. As shown in FIG. 4, it is found that the mobility is largely deteriorated when a large amount of nitrogen is contained in a region in contact with a Ge substrate.

In order to make the concentration peak of nitrogen above the center in the thickness direction, plasma nitridation or radical nitridation are preferably used for the nitrogen supplying method.

The plasma nitridation is such a nitrogen supplying method that uses nitrogen in an excited state. Other examples of the nitrogen supplying method include thermal nitridation with NH₃, NO or N₂O, and nitrogen ion implantation.

Next, it is found that the Ge substrate preferably has a surface orientation (110), and second preferably has a surface orientation (100).

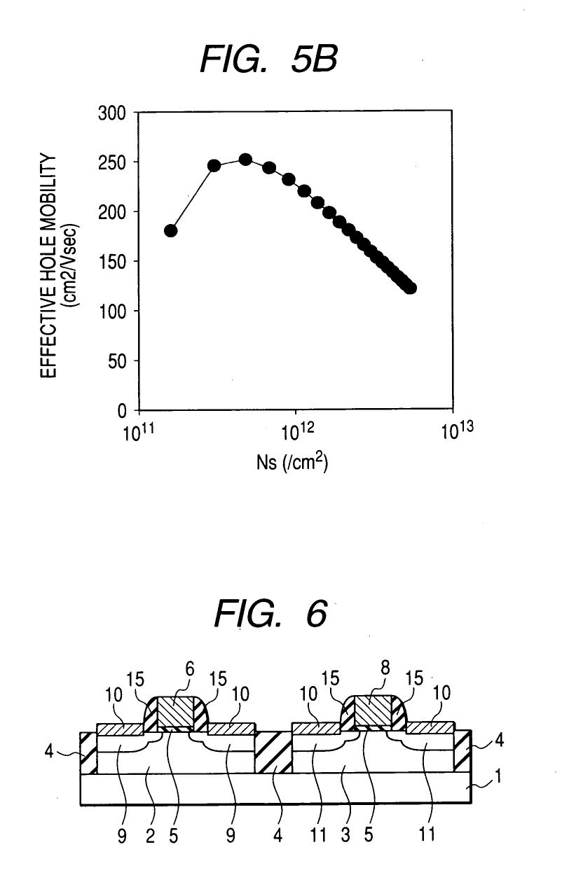

FIGS. 5A and 5B are graphs showing the dependency of the effective hole mobility of the ZrSiO/Ge structure on the orientation of the Ge substrate.

As shown in FIG. 5A, a Ge substrate having a surface orientation (111) exhibits a low mobility as compared to that having a surface orientation (100). The ZrSiO/(111)-Ge structure had a maximum value of μ_{eff} of 120 cm²/Vsec, and the ZrSiO/(100)-Ge structure had a maximum value of μ_{eff} of 170 cm²/Vsec. Also, ZrSiO/(110)-Ge structure had a maximum value of μ_{eff} of 250 cm²/Vsec as shown in FIG. 5B, and it is found that we can obtain better property when Ge p-MOSFET is fabricated on (110) surface.

Specific examples of the method for producing the semiconductor device will be described.

### Example 1

On a (100) Ge substrate having been treated with diluted hydrofluoric acid and rinsed with pure water, a Zr silicate film was deposited to 3 nm by a sputtering film forming method using Ar/O₂ plasma and Si/Zr target.

After patterning a gate resist, molybdenum was deposited with an electron beam, and a molybdenum gate electrode was formed by liftoff of the resist. A source-drain region was formed by implanting BF₂ ions at an acceleration voltage of 50 keV to a dose amount of 5×10¹⁵ cm⁻², and then subjecting to a nitrogen heat treatment at 500° C. for 30 minutes.

### Example 2

On a (100) Ge substrate having been treated with diluted hydrofluoric acid and rinsed with pure water, a ZrSiON film was deposited to 3 nm by a sputtering film forming method using Ar/O₂/N₂ plasma and Si/Zr target. The gas flow rate in the sputtering film forming method was controlled in such a manner that nitrogen was contained in a larger amount on the side of the insulating film far from the interface between the insulating film and the substrate.

After patterning a gate resist, molybdenum was deposited with an electron beam, and a molybdenum gate electrode was formed by liftoff of the resist. A source-drain region was formed by implanting BF₂ ions at an acceleration voltage of 50 keV to a dose amount of 5×10¹⁵ cm⁻², and then subjecting to a nitrogen heat treatment at 500° C. for 30 minutes.

### Example 3

On a (100) Ge substrate having been treated with diluted hydrofluoric acid and rinsed with pure water, a Zr silicate film was deposited to 3 nm by a sputtering film forming method using Ar/O₂ plasma and Si/Zr target. Furthermore, nitrogen was introduced into the insulating film by a nitrogen plasma treatment.

After patterning a gate resist, molybdenum was deposited with an electron beam, and a molybdenum gate electrode was formed by liftoff of the resist. A source-drain region was formed by implanting BF₂ ions at an acceleration voltage of 50 keV to a dose amount of 5×10¹⁵ cm⁻², and then subjecting to a nitrogen heat treatment at 500° C. for 30 minutes.

The method for forming the gate insulating film is not limited to the aforementioned sputtering deposition method but may be other ordinary methods for forming a gate insulating film including a physical deposition method, such as vapor deposition, and a chemical gas phase deposition method, such as MO-CVD and AL-CVD.

The gate electrode is not limited to molybdenum, and the method for forming the gate electrode may be an embedding method, such as damascene and replacement, and FUSI.

While the invention has been described with reference to the specific embodiments, the invention is not limited thereto and may contain various modifications within the scope of the invention. The invention can be variously modified upon practicing unless the advantages of the invention are impaired. The plural constitutional elements disclosed in the aforementioned embodiments may be appropriately combined to make other various embodiments of the invention.

What is claimed is:

1. A semiconductor device comprising:
a channel region comprising Ge;
an oxide film formed on the channel region, the oxide film comprising Si and a metallic element M selected from the group consisting of Zr, Hf, La, Ce, Pr, Nd, Pm, Sm, Eu, Gd, Tb, Dy, Ho, Er, Tm, Yb and Lu;
a gate electrode formed on the oxide film; and
source/drain regions disposed across the channel region from each other in a longitudinal direction of the channel region.

2. The semiconductor device according to claim 1, wherein the metallic element M is Zr.

3. The semiconductor device according to claim 1, wherein the metallic element M is Hf.

4. The semiconductor device according to claim 1, wherein:
the oxide film further comprises N; and
a concentration peak of the N in a thickness direction of the oxide film is closer to the gate electrode than the channel region.

5. The semiconductor device according to claim 1, wherein the channel region has a surface orientation (100).

6. The semiconductor device according to claim 1, wherein the channel region has a Ge concentration in a range of 50% to 100% based on a total amount of semiconductor elements.

7. The semiconductor device according to claim 6, wherein the channel region has 100% in the Ge concentration based on the total amount of the semiconductor elements.

8. A semiconductor device comprising
a channel region comprising Ge;
an oxide film formed on the channel region, the oxide film comprising a metallic element M selected from the group consisting of Zr, Hf, La, Ce, Pr, Nd, Pm, Sm, Eu, Gd, Tb, Dy, Ho, Er, Tm, Yb and Lu, the oxide film being in an amorphous state;
a gate electrode formed on the oxide film; and
source/drain regions disposed across the channel region from each other in a longitudinal direction of the channel region.

9. The semiconductor device according to claim 8, wherein the metallic element M is Zr.

10. The semiconductor device according to claim 8, wherein the metallic element M is Hf.

11. The semiconductor device according to claim 8, wherein:
the oxide film further comprises N; and
a concentration peak of the N in a thickness direction of the oxide film is closer to the gate electrode than the channel region.

12. The semiconductor device according to claim 8, wherein the channel region has a surface orientation (100).

13. The semiconductor device according to claim 8, wherein the channel region has a Ge concentration in a range of 50% to 100% based on a total amount of semiconductor elements.

14. The semiconductor device according to claim 6, wherein the channel region has 100% in the Ge concentration based on the total amount of the semiconductor elements.

15. A semiconductor device comprising:
a substrate;
a channel region in the substrate, the channel region containing Ge;
source/drain regions in the substrate, disposed across the channel region from each other in a longitudinal direction of the channel region;
an insulating film formed on the channel region, the insulating film containing an oxide of Si and a metallic element M selected from the group consisting of Zr, Hf, La, Ce, Pr, Nd, Pm, Sm, Eu, Gd, Tb, Dy, Ho, Er, Tm, Yb and Lu; and
a gate electrode formed on the insulating film.

16. A semiconductor device comprising:
a substrate;
a channel region in the substrate, the channel region containing Ge;
source/drain regions in the substrate, disposed across the channel region from each other in a longitudinal direction of the channel region;
an insulating film formed on the channel region, the insulating film containing an oxide of a metallic element M selected from the group consisting of Zr, Hf, La, Ce, Pr, Nd, Pm, Sm, Eu, Gd, Tb, Dy, Ho, Er, Tm, Yb and Lu, the insulating film being in an amorphous state; and
a gate electrode formed on the insulating film.
